(19) United States
(12) Patent Application Publication
(10) Pub. No.: US 2010/0311244 A1
(43) Pub. Date: Dec. 9, 2010

(54) DOUBLE-EXPOSURE METHOD

(75) Inventors: Hongmei HU, Shanghai (CN); Jun ZHU, Shanghai (CN)

Correspondence Address: RABIN & Berdo, PC, 1101 14TH STREET, NW, SUITE 500, WASHINGTON, DC, 20005, US

(73) Assignee: Shanghai IC R&D Center Co., Ltd., Shanghai (CN)

(21) Appl. No.: 12/648,010

(22) Filed: Dec. 28, 2009

(30) Foreign Application Priority Data
Jun. 9, 2009 (CN) 200910052798.3

(51) Int. Cl. H01L 21/3105; G03F 7/00

(52) U.S. Cl. 438/703; 430/312; 257/E21.119

(57) ABSTRACT

The present invention discloses a double-exposure method comprising a first lithography process and a second lithography process. Between the first and the second lithography process, coat Resolution Enhancement Lithography Assisted by Chemical Shrink (RELACS) material on the first photoresist pattern, promote thermal crosslinking reaction at the interface between the RELACS materials and the first photoresist pattern; afterwards, remove the RELACS material which does not crosslink with the first photoresist pattern. This method not only realizes higher lithography resolution, but also avoids the adverse effects of the second exposure on the first photoresist pattern in double-exposure technology.

### BACKGROUND OF THE INVENTION

1. Technical Field

The present invention relates to semiconductor manufacturing field, and more especially, to a double-exposure method.

2. Description of Related Art

With semiconductor devices scaling down, the Critical Dimension (CD) of photolithography is beyond the limit of optical lithography, which brings great challenges to semiconductor manufacturing industry, especially to photolithography technology. Extreme ultraviolet (EUV) lithography has higher resolution, but for some reason it does not appear to be ready in time. Therefore, further research and development is required in the field of optical lithography in the coming several years.

Relying on the extreme Resolution Enhancement Technology (RET), for example, Phase-Shift Mask (PSM) technology, various illumination techniques and Optical Proximity Correction (OPC) technology, etc, can further extend the application of dry lithography.

By placing an immersion fluid with high refractive index between the exposure tool lens and the resist-coated wafer, Immersion lithography can achieve higher Numerical Aperture (NA) as well as higher resolution, thus has promoted the development of photolithography.

Another technology, double patterning (DP) was developed at the right time and has been written into International Technology Roadmap for Semiconductors (ITRS). This technology is a potential way to enhance the lithography resolution without the need to change the tool infrastructure. The basic idea of double patterning is to separate one photomask into two complementary ones, and to form one photo layer through two separate exposure steps using the two different photomasks. In this way, higher lithography resolution is achieved compared with traditional single exposure method, and the service life of the lithography tools is also greatly extended.

There are several types of double patterning including Litho-Etch-Litho-Etch DP (LELE DP), Litho-Litho-Etch DP (LLE DP), Self Aligned Double Patterning (SADP) and other improved solutions.

LELE DP involves a sequence of two separate exposure and etching steps, i.e., litho-etch-litho-etch process. A first photoresist layer is exposed to form a first photoresist pattern. After transferring the pattern onto an underlying hardmask layer by etching and removing the first photoresist, a second photoresist layer is coated onto the wafer. By exposing the second photoresist layer, a second photoresist pattern is formed in between the features of the first pattern on the hardmask layer. The patterns formed during the above two exposure steps will be ultimately transferred into the final layer underneath by etching.

LLE DP technology, also known as double-exposure technology, is a sequence of two separate exposures of the same photoresist layer using two different photomasks followed by one etching process, i.e., litho-litho-etch process. In detail, a first photoresist pattern is formed followed by coating of a second photoresist layer. The second photoresist layer undergoes a second exposure to form a second pattern in between the features of the first photoresist pattern. Finally the patterns formed by the two exposure steps are transferred into the final layer by etching.

For Self-Aligned-Double-Patterning technology, a spacer is formed by deposition or reaction of the film on the previous pattern, followed by etching to remove all the film material on the horizontal surfaces, leaving only the material on the sidewalls. By removing the original patterned feature, only the spacer is left. However, since there are two spacers for every line, the line density is doubled.

Compared with LELE DP technology, LLE DP has the advantages of less etching steps and less hardmask layers, thus has to some extent reduced the production cost. However, because the second photoresist layer is directly coated on the first photoresist pattern, the second exposure will inevitably affect the first photoresist pattern. Therefore, selection of nonlinear photoresist is very important in double-exposure technology.

### SUMMARY OF THE INVENTION

The present invention aims to solve the problem in double exposure that the second exposure has an adverse effect on the patterns of the first exposure.

To this end, the present invention provides a double-exposure method, comprising a first lithography process and a second lithography process, between the first lithography process and the second lithography process, the method further comprises: coating Resolution Enhancement Lithography Assisted by Chemical Shrink (RELACS) material on the first photoresist pattern formed by the first lithography process, promoting crosslinking reaction at the interface between RELACS material and the first patterned photoresist; removing the RELACS material which does not crosslink with the first photoresist pattern.

Furthermore, the method comprises a baking step to promote thermal crosslinking reaction between RELACS material and photoresist at the interface of the two materials.

Furthermore, when baking to promote thermal crosslinking reaction between RELACS material and photoresist, the baking temperature is 90˜110□ and the baking time is 20˜30 seconds.

Furthermore, deionized water is used to remove the RELACS material which does not crosslink with the photoresist.

Furthermore, the method comprises cleaning the RELACS material with deionized water for two times and each cleaning time is 60 seconds.

Furthermore, the RELACS material is an organic polymer soluble in deionized water.

The present invention further provides a double-exposure method, comprising the following steps:

providing a silicon wafer with a bottom layer formed on the substrate;

coating a first layer of photoresist on the wafer, performing a first lithography process and forming a first photoresist pattern;

coating RELACS material on the first photoresist pattern, promoting thermal crosslinking reaction with the first photoresist at their interface;

removing the RELACS polymer which does not crosslink with the first photoresist pattern;

coating a second layer of photoresist on the wafer, performing a second lithography process and forming a second photoresist pattern;

using the first and the second photoresist patterns as hardmask, transferring the patterns into the bottom layer by etching process.

Furthermore, the method comprises a baking step to promote thermal crosslinking reaction at the interface between RELACS material and the first photoresist.

Furthermore, when baking to promote crosslinking reaction between RELACS material and the first photoresist pattern, the baking temperature is 90˜110□ and the baking time is 20˜30 seconds.

Furthermore, use deionized water to remove RELACS material which does not crosslink with the first photoresist pattern.

Furthermore, the method comprises cleaning with deionized water for two times and each cleaning time is 60 seconds.

Furthermore, after cleaning the wafer with deionized water, spinning off the deionized water and baking the wafer at low temperature.

Furthermore, the double-exposure method further comprises the steps of removing the photoresist and cleaning the wafer.

Furthermore, the line width of the first photoresist pattern is smaller than that of the second photoresist pattern.

Furthermore, the photoresist of the first and second layers is KrF photoresist.

Furthermore, the second photoresist pattern is formed in between the features of the first photoresist pattern.

Furthermore, the RELACS material is an organic polymer soluble in deionized water.

To sum up, by introducing RELACS polymer and process into double exposure process, the present invention of double exposure method not only realizes a higher lithography resolution and extends the lithography capability of present lithography tools, but also eliminates the influence of the second exposure on the first photoresist pattern, thus reducing the requirement for nonlinear photoresist in double-exposure technology.

### BRIEF DESCRIPTION OF THE DRAWINGS

FIG. 1 is the flow chart of the double-exposure method provided by an embodiment of the present invention;

FIGS. 2A-2E show the schematic process of double-exposure method according to an embodiment of the present invention.

### DETAILED DESCRIPTION OF THE INVENTION

Details of this present invention will be further described in combination with the preferred embodiments and the drawings to make the purposes and features of the present invention more obvious and more understandable.

One embodiment of the present invention provides a double-exposure method. The method comprises a first lithography process and a second lithography process. Between the first and the second lithography process, the method further comprises: coat RELACS material on the first photoresist pattern, promote thermal crosslinking reaction at the interface between RELACS material and the first photoresist pattern.

Remove RELACS material which does not crosslink with the first photoresist pattern.

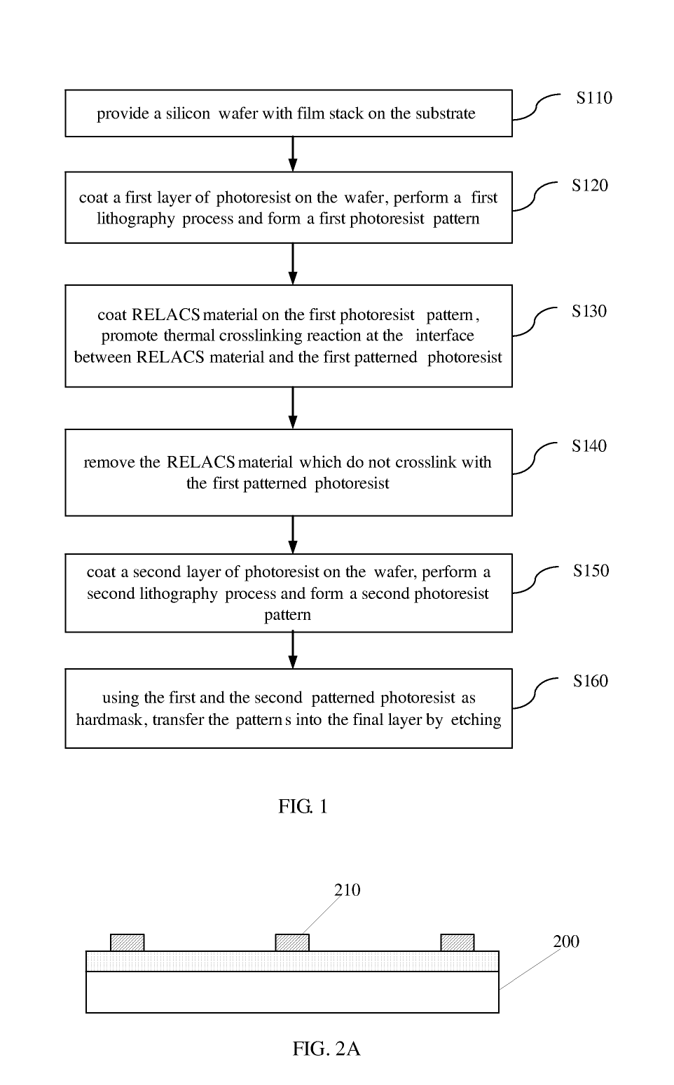

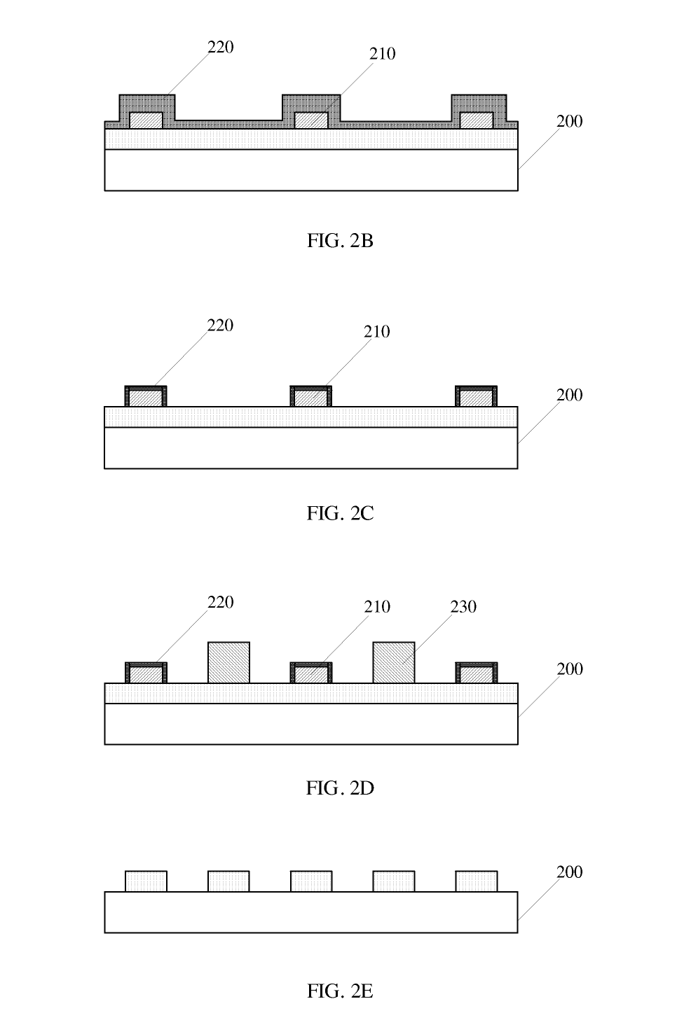

To describe the method of the embodiment more clearly and more specifically, refer to FIG. 1 of the flow chart of the double-exposure method provided by an embodiment of the present invention, and see FIGS. 2A-2E for reference, wherein the method comprises the following steps:

S110: provide a silicon wafer 200 with a bottom layer formed on the substrate;

S120: coat a first layer of photoresist on the wafer 200, perform a first lithography process and form a first photoresist pattern, as shown in FIG. 2A;

In this embodiment, the photoresist is KrF photoresist. However, this does not limit the present invention. Any photoresist capable of realizing the purpose of the present invention is within the scope of the present invention.

S130: coat RELACS material 220 on the first photoresist pattern 210, as shown in FIG. 2B, promote thermal crosslinking reaction at the interface (including side and top of the first photoresist pattern 210) between RELACS material and the first photoresist 210, as shown in FIG. 2C.

In this embodiment, the RELACS material is a water-soluble organic polymer containing water-soluble resin and crosslinking agent components, so when baked, the RELACS material 220 crosslinks with the first photoresist pattern 210 at their interface, generating a water-insoluble material at the top and side of the first photoresist pattern 210, which will protect the first photoresist underneath from being affected by the second exposure.

In this embodiment, the baking temperature is 90˜110□ and the baking time is 20˜30 seconds.

S140: since the RELACS material is an organic polymer soluble in deionized water, to completely remove the RELACS polymer 220 which does not crosslink with the first photoresist pattern 210, use deionized water to clean the wafer 200 for two times and each cleaning time is 60 seconds in this embodiment.

In this embodiment, after cleaning the wafer 200 with deionized water, spin off the water and bake the wafer 200 at low temperature.

S150: coat a second layer of photoresist on the wafer 200, perform a second lithography process and form a second photoresist pattern 230, as shown in FIG. 2D;

In this embodiment, the second photoresist pattern is formed in between the features 210 of the first exposure, and the line width of the first photoresist pattern 210 is smaller than that of the second photoresist pattern 230.

S160: using the photoresist patterns 210, 230 as hardmask, transfer the patterns 210, 230 into the bottom layer on the wafer 200 by etching, as shown in FIG. 2E.

In this embodiment, after transferring the first and second patterns 210, 230 into the bottom layer on the wafer 200, remove the photoresist and clean the wafer 200 and the double exposure process is then finished.

To sum up, by introducing RELACS polymer and process into double exposure process, this embodiment of the present invention not only realizes a higher lithography resolution and extends the lithography capability of present lithography tools, but also eliminates the influence of the second exposure on the first photoresist pattern, thus reducing the requirement for nonlinear photoresist in double-exposure technology.

The present invention is not limited by the abovementioned preferred embodiments disclosed in the present invention. Those with common knowledge of this art may make some changes and modifications without deviating from the spirit and scope of the present invention. Therefore, the protection scope of the present invention shall be subject to the scope limited by the claims.

What is claimed is:

1. A double-exposure method, comprising a first lithography process and a second lithography process, characterized in that the method further comprises the following steps between the first and the second lithography process: coating RELACS material on the first photoresist pattern formed by the first lithography process and promoting thermal crosslinking reaction at the interface between RELACS material and the first photoresist pattern; removing the RELACS material which does not crosslink with the first photoresist pattern.

2. The double-exposure method according to claim 1, characterized in that, baking to promote thermal crosslinking reaction between RELACS material and the first photoresist at the interface.

3. The double-exposure method according to claim 2, characterized in that the baking temperature is 90˜110□ and the baking time is 20˜30 seconds.

4. The double-exposure method according to claim 1, characterized in that, using deionized water to remove the RELACS material which does not crosslink with the first photoresist pattern.

5. The double-exposure method according to claim 4, characterized in that using deionized water to clean the wafer for two times and each cleaning time is 60 seconds.

6. The double-exposure method according to claim 1, characterized in that the RELACS material is an organic polymer soluble in deionized water.

7. A double-exposure method, characterized in that, comprising the following steps:
providing a silicon wafer with a bottom layer formed on the substrate;
coating a first layer of photoresist on the silicon wafer, performing a first lithography process and forming a first photoresist pattern;
coating RELACS material on the first photoresist pattern, promoting thermal crosslinking reaction at the interface between the RELACS material and the first photoresist pattern;
removing the RELACS material which does not crosslink with the first photoresist pattern;
coating a second layer of photoresist on the silicon wafer, performing a second lithography process and forming a second photoresist pattern;
using the first and the second photoresist pattern as hardmask, transferring the patterns into the bottom layer on the silicon wafer by etching process.

8. The double-exposure method according to claim 7, characterized in that, baking to promote thermal crosslinking reaction at the interface between RELACS material and the first patterned photoresist.

9. The double-exposure method according to claim 8, characterized in that when baking the RELACS material, the temperature is 90˜110□ and the time is 20˜30 seconds.

10. The double-exposure method according to claim 7, characterized in that, using deionized water to remove the RELACS material which does not crosslink with the first photoresist pattern.

11. The double-exposure method according to claim 10, characterized in that, using deionized water to clean the wafer for two times and every cleaning time is 60 seconds.

12. The double-exposure method according to claim 11, characterized in that, after cleaning the silicon wafer by deionized water, spinning off the water and baking the wafer at low temperature.

13. The double-exposure method according to claim 7, characterized in that, further comprising the steps of removing the photoresist and cleaning the silicon wafer.

14. The double-exposure method according to claim 7, characterized in that, the line width of the first photoresist pattern is smaller than that of the second photoresist pattern.

15. The double-exposure method according to claim 7, characterized in that, the photoresist of the first and second layers is KrF photoresist.

16. The double-exposure method according to claim 7, characterized in that, the second photoresist pattern is formed in between the features of the first photoresist pattern.

17. The double-exposure method according to claim 7, characterized in that, the RELACS material is an organic polymer soluble in deionized water.
